(19) United States
(12) Patent Application Publication
(10) Pub. No.: US 2026/0344216 A1
(43) Pub. Date: Oct. 29, 2026

(54) HYDRAULIC DRIVE SYSTEM FOR AIRCRAFT LANDING GEAR

(71) Applicant: Albert Ben Currey, Phoenix, AZ (US)

(72) Inventor: Albert Ben Currey, Phoenix, AZ (US)

(21) Appl. No.: 19/569,520

(22) Filed: Mar. 17, 2026

Related U.S. Application Data
(63) Continuation-in-part of application No. 19/254,262, filed on Jun. 30, 2025.
Application No. 19/254,262 is a division of application No. 18/310,594, filed on May 2, 2023, now Pat. No. 12,733,358.
Application No. 18/310,594 is a continuation-in-part of application No. 18/184,161, filed on Mar. 15, 2023, now Pat. No. 11,826,782.

(51) Int. Cl. H10K 59/131; G06T 7/00; G06T 7/70; H10K 71/70

(52) U.S. Cl. CPC H10K 59/131; G06T 7/0004; G06T 7/70; H10K 71/70

(57) ABSTRACT

A drive system for aircraft landing gear includes a manifold with fluid inlet and outlet orifices and an inner volume containing a pressure chamber. A power generating member positioned within the manifold's inner volume has a grooved drive with recessed grooves on its outer surface. A hub couples to the power generating member for attachment to aircraft landing gear wheels. A hub aperture extends through both the hub and power generating member. An axle extends through the hub aperture with two tapered bearings positioned within the aperture and coupled to the axle. The hub rotates around the axle when hydraulic fluid flows through the manifold and engages the power generating member's grooved drive.

### CROSS-REFERENCE TO RELATED APPLICATIONS

This application is a continuation-in-part of earlier U.S. Utility patent application Ser. No. 19/254,262, filed Jun. 30, 2025, which is a division of U.S. Utility patent application Ser. No. 18/310,594, filed May 2, 2023, now U.S. Pat. No. 12,577,969, issued Mar. 17, 2026, which is a continuation-in-part of the earlier U.S. Utility patent application Ser. No. 18/184,161, filed Mar. 15, 2023, now U.S. Pat. No. 11,826,782, issued Nov. 28, 2023, the disclosures of which is hereby incorporated entirely herein by reference.

### BACKGROUND

### Technical Field

The present disclosure relates to aircraft landing gear systems, and more particularly to a hydraulic drive system for rotating landing gear wheels prior to aircraft landing to reduce tire wear and improve runway maintenance.

### State of the Art

Aircraft landing operations subject landing gear wheels to extreme forces and stresses during touchdown. When an aircraft approaches for landing, the wheels are stationary while the aircraft maintains forward velocity. Upon contact with the runway, the wheels must rapidly accelerate from zero rotational speed to match the aircraft's ground speed, creating substantial friction between the tire and runway surface.

This sudden transition from stationary to rotating generates considerable heat and mechanical stress, leading to accelerated tire wear and the deposition of rubber particles on runway surfaces. The friction forces during this initial contact phase can cause tire skidding, flat spotting, and premature degradation of tire tread compounds. These effects reduce tire service life and increase maintenance costs for aircraft operators.

Runway maintenance presents additional challenges as accumulated rubber deposits from repeated aircraft landings can reduce surface friction coefficients and compromise braking performance for subsequent aircraft operations. Airport authorities must regularly perform runway cleaning operations to remove these rubber deposits, requiring specialized equipment and causing operational disruptions.

Various approaches have been explored to address these challenges in aircraft landing operations. Some systems have attempted to pre-rotate landing gear wheels using electric motors, while others have investigated pneumatic or mechanical drive mechanisms. However, many existing approaches face limitations related to power requirements, system complexity, weight considerations, and integration with existing aircraft hydraulic systems.

Aircraft hydraulic systems provide substantial power for operating various aircraft components including flight control surfaces, landing gear retraction mechanisms, and braking systems. These hydraulic systems typically operate at high pressures and can deliver considerable mechanical power. The availability of hydraulic power throughout aircraft operations makes hydraulic systems attractive for powering auxiliary equipment and subsystems.

Improvements in landing gear wheel pre-rotation systems could provide benefits for aircraft operators through reduced tire replacement costs, extended tire service intervals, and decreased runway maintenance requirements. Such improvements could also contribute to enhanced operational efficiency and reduced environmental impact from tire waste and runway cleaning operations.

### SUMMARY OF THE INVENTION

In one embodiment, a drive system for aircraft landing gear is provided. The drive system includes a manifold having a fluid inlet orifice, a fluid outlet orifice, and an inner volume with a pressure chamber formed therein. The drive system includes a power generating member positioned within the inner volume of the manifold, the power generating member having a grooved drive with a plurality of recessed grooves formed in an outer surface thereof. The drive system includes a hub coupled to the power generating member, the hub configured for attachment to a wheel of the aircraft landing gear. The drive system includes a hub aperture extending through the hub and the power generating member. The drive system includes an axle extending through the hub aperture. The drive system includes two tapered bearings positioned within the hub aperture and coupled to the axle, wherein the hub is configured to rotate around the axle when hydraulic fluid from the aircraft flows through the manifold and engages the grooved drive of the power generating member.

In another embodiment, a drive system for aircraft landing gear is provided. The drive system includes a hydraulic motor having a manifold with an inner volume comprising a cylindrical surface, a fluid inlet orifice, and a fluid outlet orifice. The drive system comprises a power generating member disposed within the inner volume, the power generating member comnprising a shaft having a diameter smaller than a diameter of the cylindrical surface and including a grooved drive with a plurality of recessed grooves evenly spaced around a circumference of the power generating member. The drive system includes a pressure chamber formed in the manifold and including a pressure channel formed in the cylindrical surface, the pressure channel overlapping the inlet orifice and extending below the inlet orifice. The drive system includes a hub coupled to the power generating member and configured to mount to a wheel of the aircraft landing gear. The drive system includes an axle extending through the hub and the power generating member, wherein hydraulic fluid flowing through the inlet orifice engages the grooved drive through the pressure channel to rotate the power generating member and the hub.

In yet another embodiment, a method of operating a drive system for aircraft landing gear is provided. The method includes providing a manifold having a fluid inlet orifice, a fluid outlet orifice, an inner volume, and a pressure chamber within the inner volume. The method includes providing a power generating member within the inner volume of the manifold, the power generating member being coupled to a hub configured for attachment to a wheel of the aircraft landing gear. The method includes flowing hydraulic fluid from the aircraft into the manifold through the inlet orifice and into the pressure chamber. The method includes directing the hydraulic fluid through the pressure chamber to engage the power generating member to rotate the power generating member and the hub. The method includes rotating the wheel of the aircraft landing gear to a predetermined speed prior to landing the aircraft. The method includes flowing hydraulic fluid from the pressure chamber and out of the manifold through the outlet orifice.

The foregoing and other features and advantages of the present invention will be apparent from the following more detailed description of the particular embodiments of the invention, as illustrated in the accompanying drawings.

### BRIEF DESCRIPTION OF THE DRAWINGS

A more complete understanding of the present invention may be derived by referring to the detailed description and claims when considered in connection with the Figures, wherein like reference numbers refer to similar items throughout the Figures, and:

FIG. 1 is a perspective view of a hydraulic vibration generating device according to an embodiment;

FIG. 2 is a perspective view of a manifold and a vibration generating member of a hydraulic vibration generating device according to an embodiment;

FIG. 3A is a perspective exploded view of a hydraulic vibration generating device according to an embodiment;

FIG. 3B is a perspective exploded view of a hydraulic motor according to an embodiment;

FIG. 4 is a perspective view of a manifold for use with a hydraulic vibration generating device or hydraulic motor according to an embodiment;

FIG. 5 is a perspective view of a manifold for use with a hydraulic vibration generating device or hydraulic motor according to an embodiment;

FIG. 6 is a side view of a manifold for use with a hydraulic vibration generating device or hydraulic motor according to an embodiment;

FIG. 7 is a section view of a manifold for use with a hydraulic vibration generating device or hydraulic motor according to an embodiment;

FIG. 8 is a top view of a drive system for landing gear, in accordance with an embodiment;

FIG. 9 is an exploded view of the drive system for landing gear, in accordance with an embodiment;

FIG. 10 is an exploded perspective view of the drive system for landing gear, in accordance with an embodiment;

FIG. 11 is a perspective view of a manifold showing internal structure and fluid flow passages, in accordance with an embodiment;

FIG. 12 is a perspective view of the manifold and internal structure, in accordance with an embodiment;

FIG. 13 is a section view of the manifold showing internal fluid flow configuration, in accordance with an embodiment;

FIG. 14 is a perspective view of a hub assembly for landing gear, in accordance with an embodiment; and

FIG. 15 is a section view of a drive member assembly showing internal structure and fluid flow path, in accordance with an embodiment.

### DETAILED DESCRIPTION OF EMBODIMENTS OF THE INVENTION

As discussed above, embodiments of the present invention relate to a hydraulic drive system for rotating landing gear wheels prior to aircraft landing to reduce tire wear and improve runway maintenance.

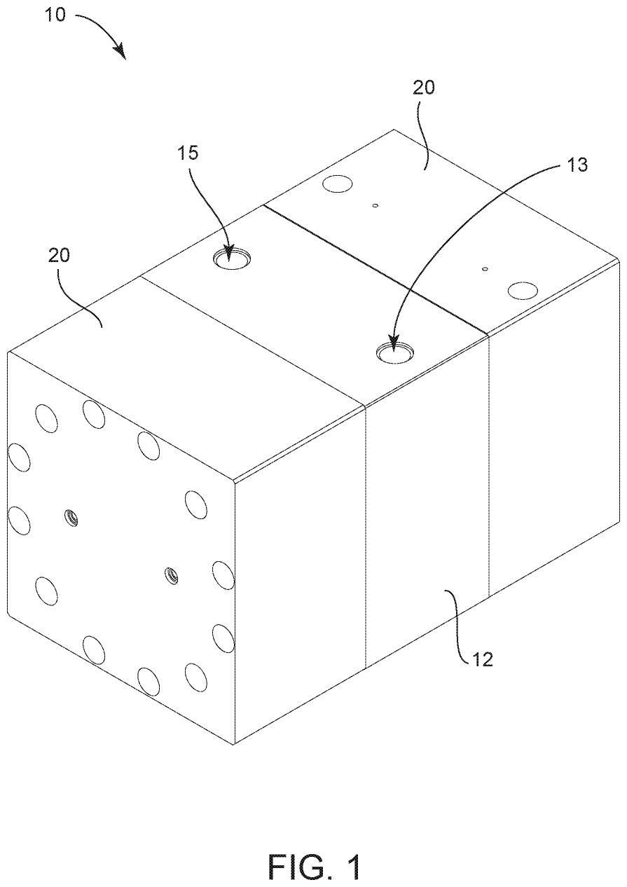

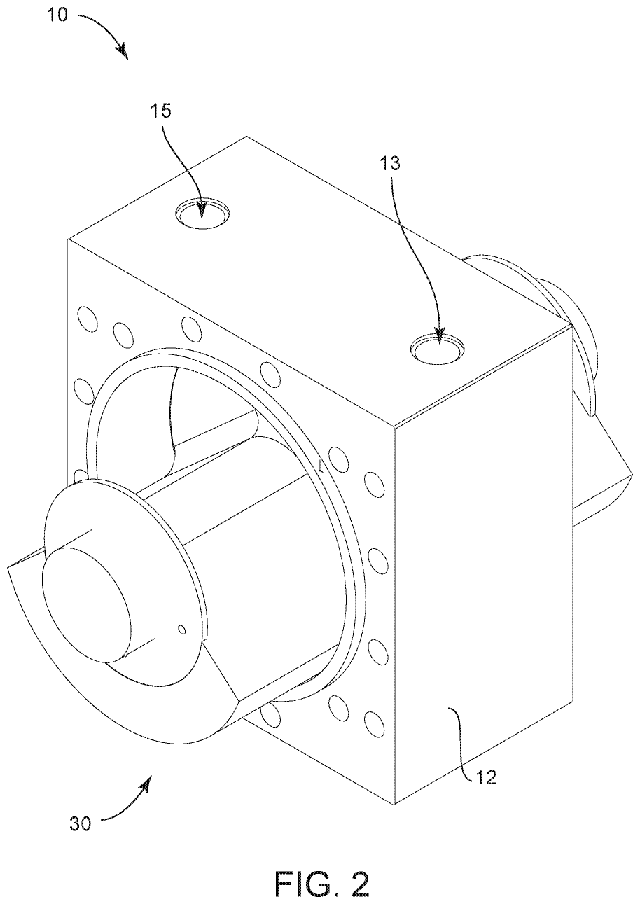

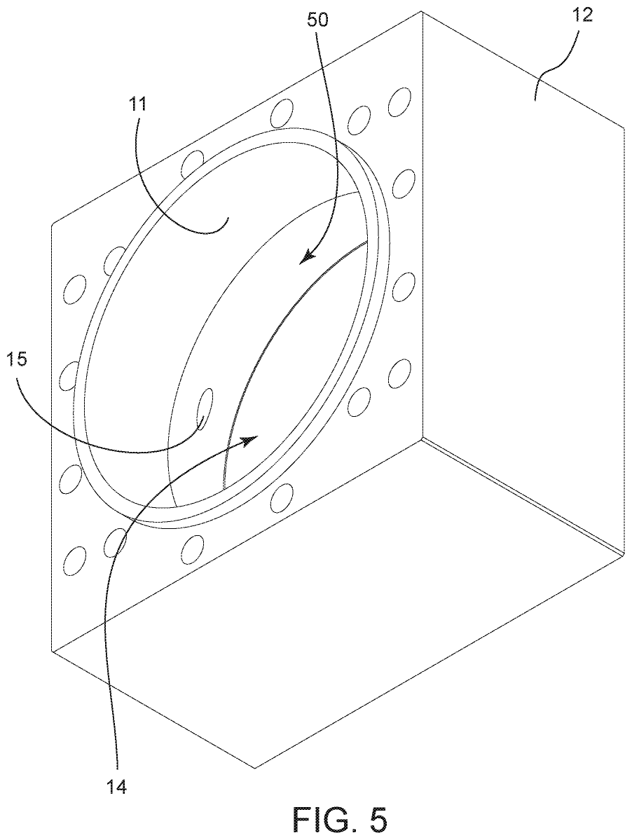

The hydraulic drive operates in manner as disclosed in the hydraulic vibration device/hydraulic motor disclosed in FIGS. 1-7.

Referring to the drawings, FIGS. 1-7 depict an embodiment of a hydraulic driven vibration generating device 10. The device 10 generally comprises a manifold 12, retaining plates 20, and a vibration generating member 30, wherein the vibration generating member 30 is retained within the manifold 12 by coupling the retaining plates 20 to the manifold 12.

The manifold 12 may be a block shape or other shape that is needed for the operation of the vibration generating device 10. The manifold 12 may comprise an inner volume 14 that may be defined by a cylindrical surface 11 with a diameter forming an aperture extending through the manifold 12, wherein the aperture may be bounded on each end by coupling the retaining plates 20 on opposing side of the manifold 12. The manifold 12 may also comprise an inlet orifice 13 and an outlet orifice 15. This allows hydraulic fluid to flow into the manifold 12 through the inlet orifice 13 and into the inner volume 14 to engage and rotate the vibration generating member 30, and then out through the outlet orifice 15. The outlet orifice 15 has a larger opening to the inner volume 14 than the inlet orifice 13 in order to remove fluid from the inner volume as quickly as possible. In some embodiments, the size of the outlet orifice 15 may vary and the shape of the outlet orifice 15 may vary depending on the size and use application of the vibration generating device 10. An inlet hose adapter (not shown) may be coupled between the inlet orifice 13 and an inlet hose and an outlet hose adapter (not shown) may be coupled between the outlet orifice 15 and an outlet hose, thereby allowing a fluid inlet hose and a fluid outlet hose to be coupled to the manifold 12 for operation of the device 10.

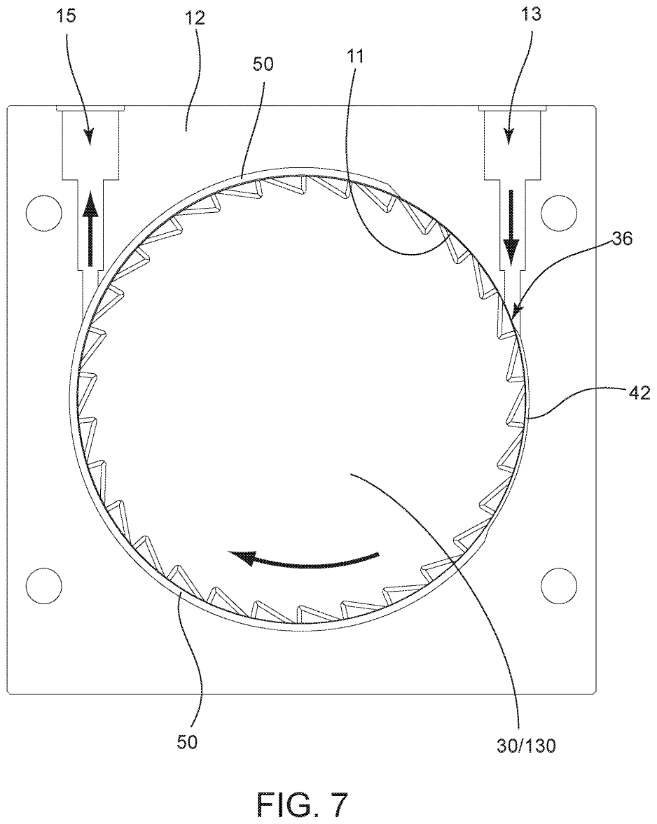

The vibration generating member 30, formed as a spool, may comprise a shaft 34 having voids 32 formed or cut into a portion or portions of the shaft 34. The voids 32 reduce weight on one side of the shaft 34 thereby creating a weighted side of the shaft 34, wherein the center of gravity is offset from the axis and is located toward the weighted side of the shaft 34 and not on the axis of the shaft, thereby making the weight “off-center”. The shaft 34 of the vibration generating member 30 is rotatable within the inner volume 14 of the manifold 12. The rotation of the shaft 34 with the off-center weight or offset center of gravity results in vibration of the manifold 12. As shown in FIG. 7, the diameter of the shaft 34 is smaller than the diameter of the cylindrical surface 11 of the inner volume 14, wherein the difference between the diameter of the shaft 34 and the diameter of the cylindrical surface 11 of the inner volume 14 is such to inhibit hydraulic oil from traveling between the shaft 34 and the cylindrical surface 11.

The vibration generating member 30, formed as a spool, comprises a grooved drive 36 formed in the outer surface of the shaft 34 around a circumference of the shaft 34. The grooved drive 36 comprises a plurality of grooves 38 formed in the outer surface of the shaft 34 and are evenly spaced around the circumference of the shaft 34, such that hydraulic fluid may engage the grooves 38 to rotate the shaft 34. The vibration generating member 30 may also include ends 39 that engage a bearing and cover plates 35 that are coupled around the ends 39 to separate the ends and cover the bearings that are within the retaining plates 20

The manifold 12 comprises a pressure chamber 40. The pressure chamber 40 may comprise a pressure channel 42 formed in the cylindrical surface 11 of the inner volume 14. A first end 43 of the pressure channel 42 is located in a position that overlaps the inlet orifice 13 between the lower end 17 and the upper end 19 of the inlet orifice 13 without extending past the upper end 19. The pressure channel 42 then extends past the lower end 17 until terminating at a second end 45 of the pressure channel 42. The pressure channel 42 forms side walls 44 and the length of the side walls 44 may be equal along the length of the pressure channel 42.

The diameter of the shaft 34 is smaller than the diameter of the inner volume 14 that forms a seal extending from the first end 43 of the pressure channel 42 to above the upper end 19 of the inlet orifice 13 and on either side of the pressure channel 42. The seal does not include the pressure channel 42 and operates to form a space between the cylindrical surface 11 of the inner volume 14 and the shaft 34 that is small enough to inhibit hydraulic oil from traveling up and around the shaft 34 in a direction opposite of the direction of rotation of the shaft 34. This results in reduction of pressure in a direction opposing the direction of rotation of the shaft 34 and allows the shaft 34 to rotate in the proper direction more easily than if the seal portion did not exist. The pressure channel 42 and seal forms the pressure chamber 40 between the groove drive 36 of the shaft 34 and the pressure channel 42, thereby ensuring that the pressure being produced by pumping of hydraulic oil into the inlet orifice 13 is located within the space bound on four sides by the pressure channel 42 and on a fifth side by the groove drive 36 of the shaft 34, with only one exit for the hydraulic oil, the exit located at the lower end 45 of the pressure channel 42.

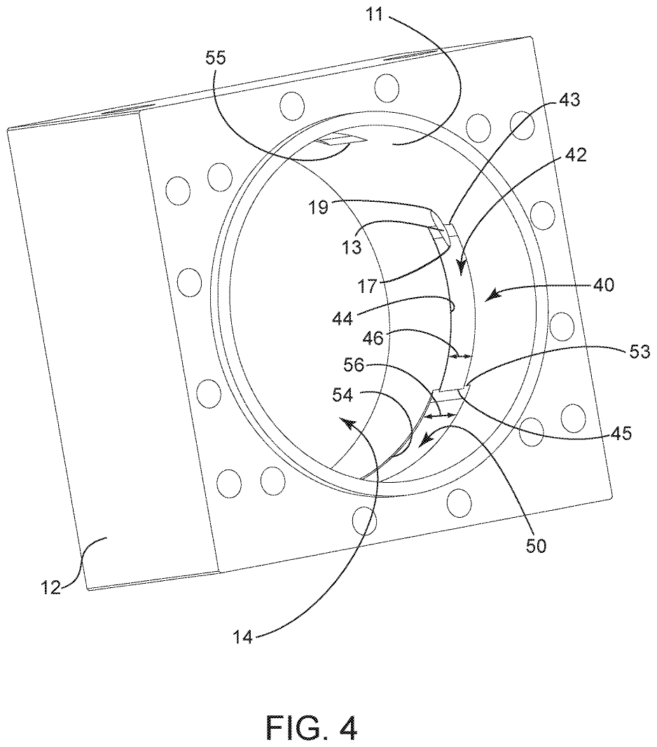

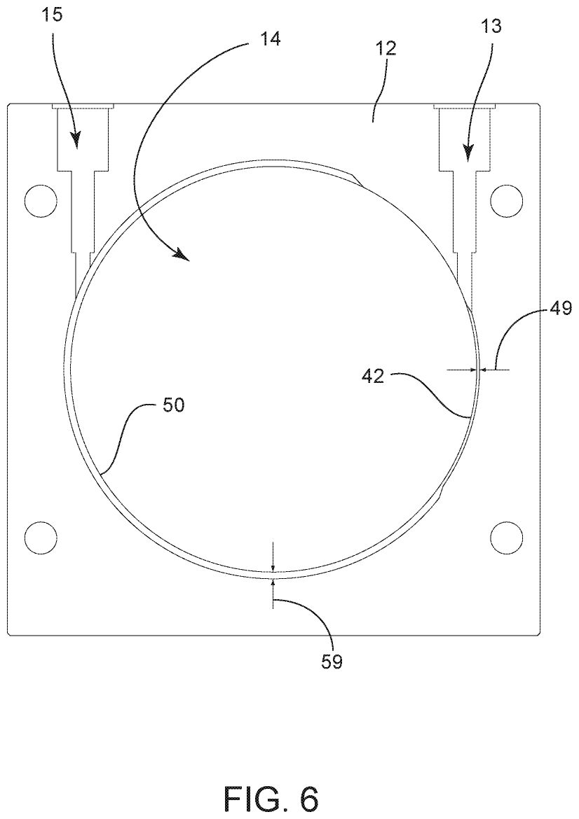

The length of the pressure channel 42 may have varying lengths. In embodiments, the length the pressure channel 42 extending below the inlet orifice may be at least as long as at least two grooves 38, as shown in FIGS. 4, 6A and 7. However, various lengths of pressure channel 42 may be utilized, such as shown in FIG. 6B, and the length may extend between the inlet orifice 13 and the outlet orifice 15 in the direction of rotation. Additionally, in embodiments, a width 46 of the pressure channel 44 may be equal to or less than a width 37 of the grooves 38 of the groove drive 36 of the shaft 34.

The manifold 12 may further include a pressure relief channel 50 formed in cylindrical surface 11 of the inner volume 14, wherein the pressure relief channel 50 comprises a depth 59 that is greater than the depth 49 of the pressure channel 42, as shown in FIGS. 6 and 7, depicting exaggerated depths 59 and 49 of the pressure relief channel 50 and the pressure channel 42 respectively to better depict the differences in the depths of the channels. A first end 53 of the pressure relief channel 50 is located in a position that is adjacent to and overlaps or abuts the second end 45 of the pressure channel 42. The pressure relief channel 50 then extends past the outlet orifice 15 until terminating at a second end 55 of the pressure relief channel 50. The pressure relief channel 50 forms side walls 54 and the length of the side walls 54 may be equal along the length of the pressure relief channel 50. Further, the width 56 of the pressure relief channel 50 is greater than the width 46 of the pressure channel 42. Because of the greater width 56 of the pressure relief channel 50, upon exiting the pressure channel 42, the hydraulic oil may be dispersed into the pressure relief channel 50 and flow out of the manifold 12 through the outlet orifice 15. This pressure chamber 40 operates to reduce pressure acting on the shaft 34 in a direction opposite the direction of rotation, thereby adding efficiency and increased performance of the vibration generating member 30.

Without the pressure chamber 40, the block pressure fights against the rotation of the shaft 34 and prevents the shaft 34 from rotating, particularly when the system and hydraulic oil is cold. With the pressure chamber 40, the block pressure is reduced and essentially all of the reduction of block pressure is recovered in the pressure chamber 40 and directed in the path of least resistance through the pressure channel 42 to engage the grooved drive 36 of the shaft 34.

In operation, hydraulic oil is flowed into the inlet orifice 13 and engages the grooves 38 of the groove drive 36 of the shaft 34 of the vibration generating member 30. The hydraulic oil engages the grooves 38 within the pressure chamber, wherein the pressure of the hydraulic oil, because of the small pace between the groove drive 36 and the pressure channel 44, is higher than the pressure within the pressure relief channel 50 and the rest of the block and operates to rotate the vibration generating member 30 in a direction of rotation toward the outlet orifice 15. As the hydraulic oil travels through the pressure channel 42 rotating the shaft 34, the hydraulic oil exits the pressure chamber 40 at the lower end 45 of the pressure channel 42 and the pressure is relieved into the pressure relief channel 50 and the hydraulic oil can then exit the inner volume 14 of the manifold 12 through the outlet orifice 15. The rotation of the vibration generating device 13 creates vibration that can be utilized in various applications.

The manifold 12 may have various apertures and recesses that are utilized to couple the retaining plate 20 to the manifold 12 and for use of couplers to couple the manifold 12 to an external device to vibrate. While these apertures and recesses are shown, they are only for exemplary purposes and should not be considered a limitation, but simply as one way that certain components of a hydraulic vibration generating device 10 may be coupled together. Other forms of coupling components together are contemplated and may be used without departing from the scope of the invention and claims.

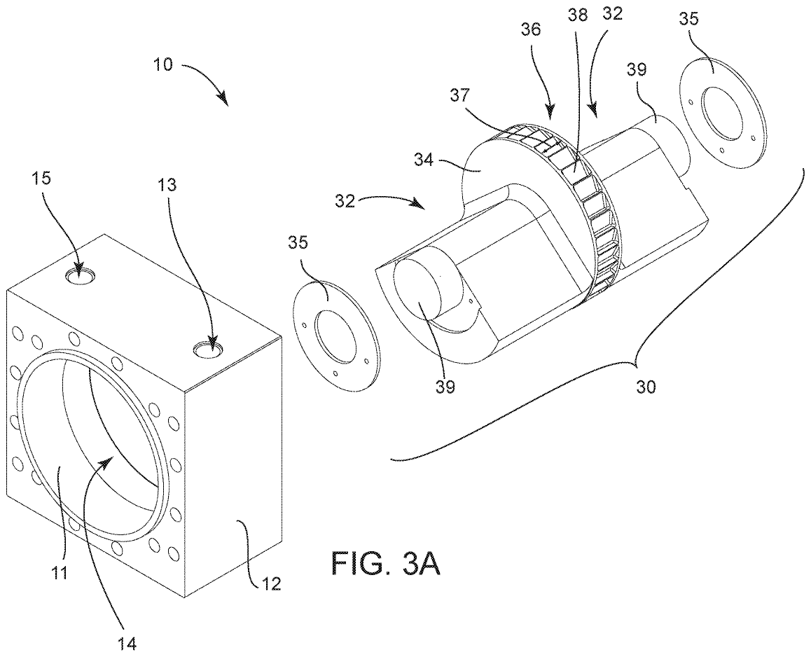

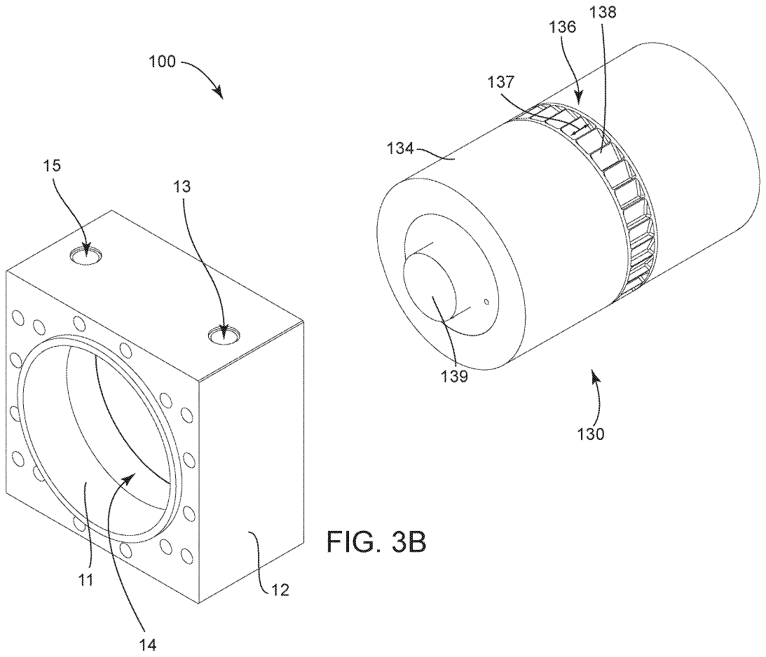

In another embodiment, shown in FIGS. 3B and 7 the vibration generating member 30 is replaced with a power generating member 130, formed as a spool, that comprises a solid shaft 134 and operates as a motor and can be coupled to an external device to supply power. The power generating member 130, formed as a spool, comprises a grooved drive 136 formed in the outer surface of the shaft 134 around a circumference of the shaft 134. The grooved drive 136 comprises a plurality of grooves 138 formed in the outer surface of the shaft 134 and are evenly spaced around the circumference of the shaft 134, such that hydraulic fluid may engage the grooves 138 to rotate the shaft 134 to generate power, such as through a drive shaft to supply power operate an external device. Further, the grooves 138 comprise a width 137 having the same characteristics as the width 37 of the grooves 38 of the vibration generating member 30. The operation of the manifold 12 with the pressure chamber 40 is the same in a hydraulic motor 100 as it is with vibration generating device 10 wherein the power generating member 130 is the same as the vibration generating member 30 without the off-center weight. This means that the method of operating a hydraulic motor with the manifold 12 is the same as the method of operating a hydraulic vibration generation device 30 with the manifold 12.

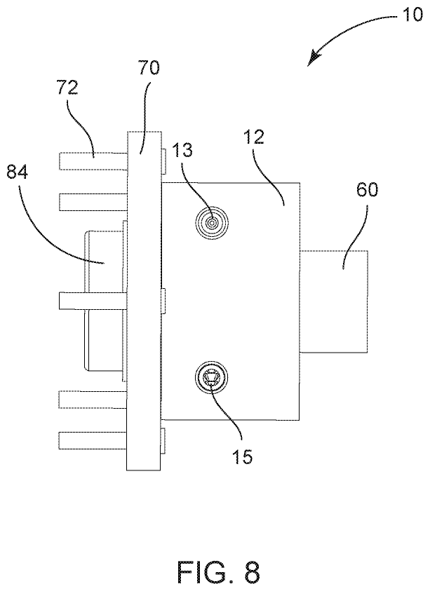

The hydraulic motor as described in FIGS. 1-7 may then be utilized as a drive system for aircraft landing gear. FIGS. 8-15 depict embodiments of a drive system for aircraft landing gear.

Referring to FIG. 8, a drive system for aircraft landing gear may include a drive member 100 that comprises a manifold 12 with an inlet orifice 13 and an outlet orifice 15. The drive system may further include an axle 60, a hub 70 with studs 72, and a cap 84. The manifold 12 may be positioned centrally within the assembly and may provide fluid flow passages for hydraulic fluid operation. The hub 70 may be coupled to the manifold 12 and may extend outward from the manifold 12, with the studs 72 protruding from the hub 70 to provide mounting points for attachment of a wheel of the aircraft landing gear. The axle 60 may extend through the center of the assembly, passing through the manifold 12 and the hub 70, allowing the hub 70 to rotate around the axle 60.

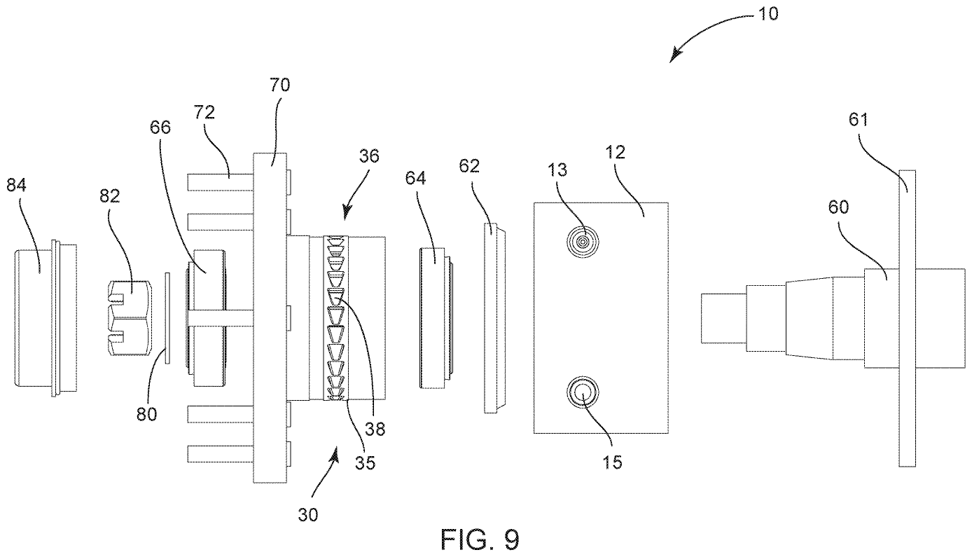

With reference to FIG. 9, an exploded view shows the relationship and assembly sequence of the drive system components. The drive member 100 may include the manifold 12 with the inlet orifice 13 and the outlet orifice 15, where the manifold 12 may be depicted as a rectangular block with circular features representing the fluid orifices. A power generating member 30 may be positioned within the manifold 12 and may include a grooved drive 36 featuring multiple grooves 38 arranged in a pattern. The grooves 38 may appear as triangular or chevron-shaped elements that extend across the surface of the grooved drive 36. In some embodiments, the plurality of recessed grooves may be evenly spaced around a circumference of the power generating member 30. The power generating member 30 may further comprise a raised surface 35 having a width greater than the width of the pressure channel 42, the raised surface 35 extending around the circumference of the power generating member 30, wherein the plurality of recessed grooves 38 are formed in the raised surface 35.

The drive system may further include a first bearing 64 and a second bearing 66, which may be disc-shaped components that facilitate rotational movement within the assembly. In some embodiments, the first bearing 64 and the second bearing 66 may be tapered bearings positioned within a hub aperture that extends through the hub 70 and the power generating member 30. The hub 70 may be illustrated with the studs 72 extending from a surface of the hub 70, providing mounting points for attachment to other components of the landing gear wheel assembly. The axle 60 may extend through bearings 64 and 66 and thereby couples the axle 60 to the power generating member 30 and therefore couples the axle 60 to the hub 70.

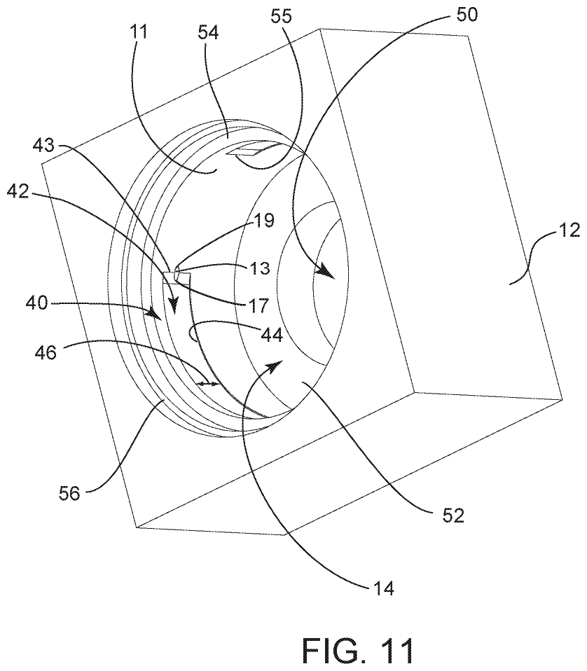

As shown in FIG. 9, additional components may include the axle 60, a rod wiper 62, a washer 80, a lock nut 82, and the cap 84. The rod wiper 62 may be positioned adjacent to the power generating member 30 within the inner volume 14. The rod wiper 62 engages the outer surface of the power generating member 30 and engages the first lip 54 and the second lip 56 of the manifold 12 (see FIG. 11). The axle 60 may extend through the center of the assembly, while the washer 80 and the lock nut 82 may provide fastening functionality. The cap 84 may cover a the washer 80 and the lock nut 82 of the assembly. The axle 60 may further comprise a plate 61 utilized to coupled to the landing gear wherein the plate operates to maintain the axle 60 and the manifold 12 is a stationary position.

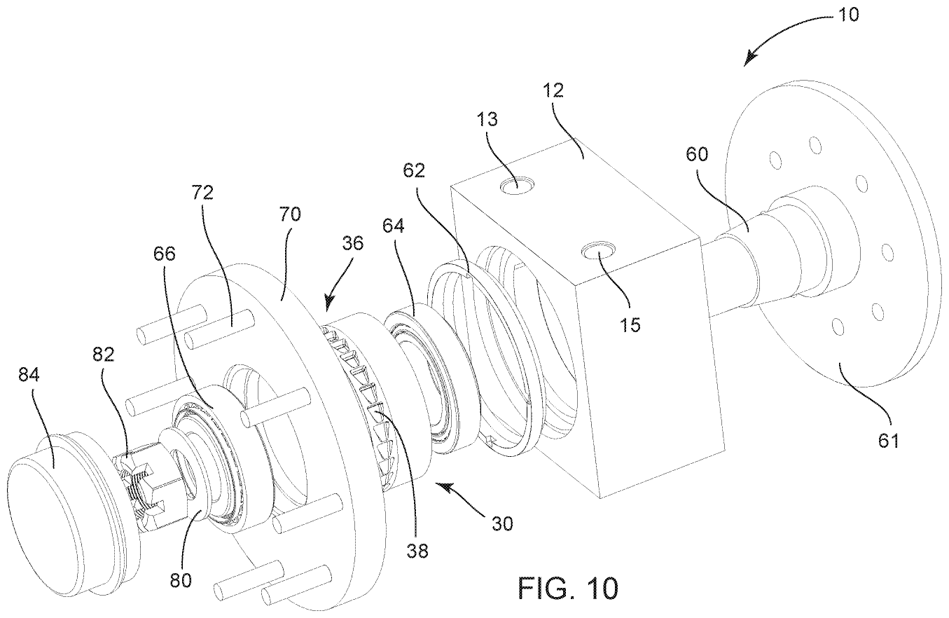

Referring to FIG. 10, an exploded perspective view demonstrates how the manifold 12 may house internal passages for directing hydraulic fluid through the system. The power generating member 30 may be positioned adjacent to the manifold 12 and may include the grooved drive 36 with the multiple grooves 38 formed on a cylindrical surface of the power generating member 30. The grooves 38 may be configured to receive hydraulic fluid and convert fluid pressure into rotational motion. In some embodiments, the hub 70 may be coupled to the power generating member 30 or may be formed as a single component with the power generating member 30. The hub 70 may be positioned to include the multiple studs 72 extending from a surface of the hub 70 for mounting a wheel. The cap 84 may be positioned to cover an outer end of the hub 70, with the washer 80 and the lock nut 82 provided for securing the assembly and then the cap 84 covering the washer 80 and the lock nut 82.

The drive system may operate such that hydraulic fluid from the aircraft flows into the manifold 12 through the inlet orifice 13 and engages the grooves 38 of the grooved drive 36 on the power generating member 30. The hydraulic fluid may then exit through the outlet orifice 15. The rotation of the power generating member 30 may cause the hub 70 to rotate around the axle 60, which may be supported by the first bearing 64 and the second bearing 66. The studs 72 on the hub 70 may provide mounting points for attaching a landing gear wheel, enabling the wheel to be rotated to a predetermined speed prior to landing the aircraft. In some embodiments, the drive system may rotate the wheels up to the predetermined speed prior to landing, which may reduce tire tread loss and increase tire life.

Referring to FIG. 11, the manifold 12 may include a cylindrical surface 11 that defines an inner volume 14 within the manifold 12. The inner volume 14 may serve as a fluid distribution space for directing hydraulic fluid through the drive system. An axle aperture 50 may extend through a center of the manifold 12, with an axle wall 52 forming an inner boundary of the axle aperture 50. In some embodiments, a first lip 54 and a second lip 56 may be positioned at one end of the manifold 12 opposite the end of the manifold 12 having the axle wall 52.

The manifold 12 may contain a pressure chamber 40 formed within the inner volume 14. The pressure chamber 40 may include a pressure channel 42 formed in the cylindrical surface 11 of the inner volume 14. As shown in FIG. 11, the pressure channel 42 may have a width 46 and may be defined by side walls 44. The pressure channel 42 may overlap the inlet orifice 13 and may extend below the inlet orifice 13. The pressure channel 42 may be configured to receive hydraulic fluid from the inlet orifice 13 and direct the hydraulic fluid to engage the grooved drive 36 of the power generating member 30. The arrangement of the pressure channels 42 along the cylindrical surface 11 may enable controlled fluid flow to generate rotational motion in the drive system.

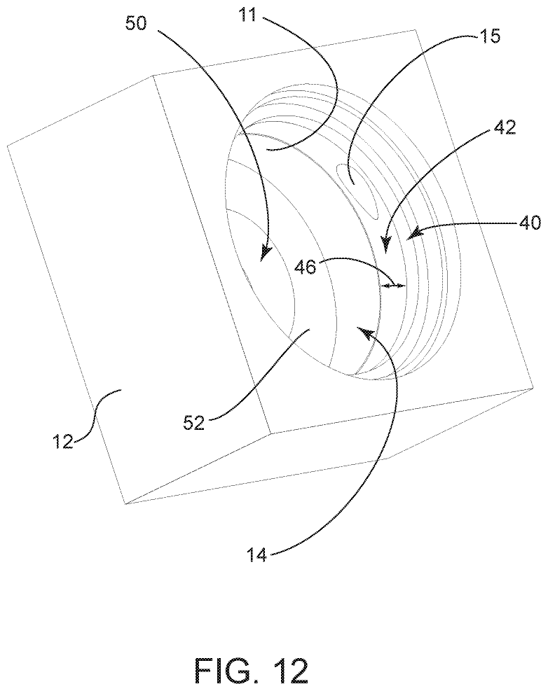

As shown in FIG. 12, the manifold 12 may include the cylindrical surface 11 that defines the inner volume 14. The outlet orifice 15 may be positioned on the cylindrical surface 11 for fluid egress from the manifold 12. The pressure chamber 40 may be formed within the inner volume 14 and may communicate with the pressure channel 42. The pressure channel 42 may have the defined width 46 and may be configured to direct hydraulic fluid flow within the manifold 12. In some embodiments, the pressure channel 42 may be positioned to engage with the power generating member 30 when assembled.

The pressure chamber 40 may further include a seal extending from a first end of the pressure channel 42 to above the inlet orifice 13 and on either side of the pressure channel 42. The seal may be formed by a space between the cylindrical surface 11 of the inner volume 14 and the raised surface 35 the power generating member 30 that may be small enough to inhibit hydraulic fluid from traveling around the power generating member 30 in a direction opposite to a direction of rotation of the power generating member 30. In some embodiments, flow of hydraulic fluid may be inhibited between the power generating member 30 and the seal and may be directed through the pressure channel 42 while engaging the grooved drive 36.

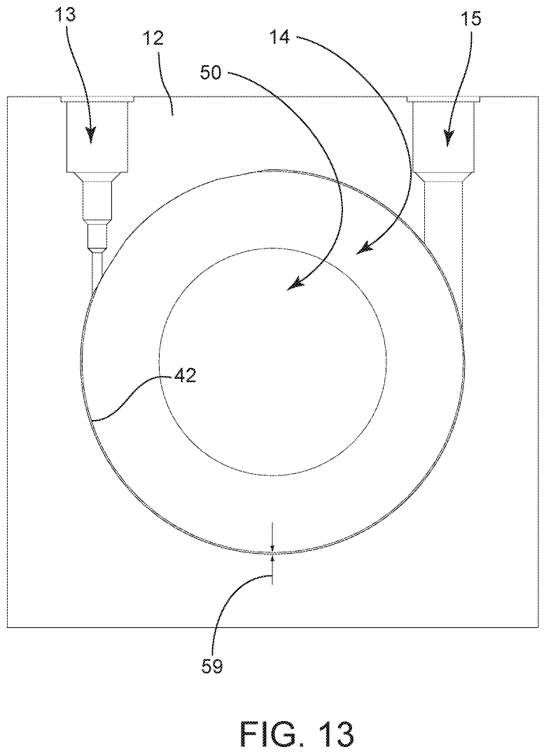

Referring to FIG. 13, a section view of the manifold 12 may show an internal fluid flow configuration. The manifold 12 may include the inlet orifice 13 positioned on a left side and the outlet orifice 15 positioned on a right side. The inner volume 14 may be defined within the manifold 12 and may contain the pressure channel 42 that may form a circular flow path having a depth 59. The pressure channel 42 may direct hydraulic fluid flow from the inlet orifice 13, through the pressure channel 42, and toward the outlet orifice 15.

The manifold 12 may further include a pressure relief channel formed in the cylindrical surface 11 and extending from the pressure channel 42 past the outlet orifice 15. In some embodiments, pressure may be relieved as hydraulic fluid flows from the pressure channel 42 into the pressure relief channel and out of the manifold 12 through the outlet orifice 15. The pressure relief channel allows hydraulic fluid to be dispersed upon exiting the pressure channel 42.

The width 46 of the pressure channel 42 may be equal to or greater than a width of the plurality of recessed grooves 38 of the grooved drive 36. In some embodiments, the width 46 of the pressure channel 42 may be configured to align with the grooves 38 to enable hydraulic fluid to engage the grooves 38 and rotate the power generating member 30. The configuration of the pressure channel 42 around the axle aperture 50 may enable hydraulic fluid to engage the power generating member 30 positioned within the inner volume 14, thereby facilitating rotation of the hub 70 and wheel assembly.

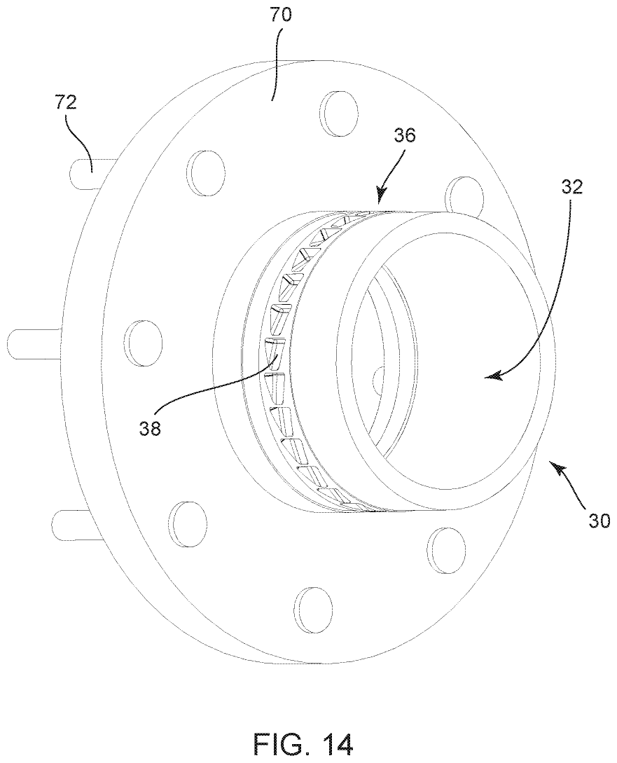

Referring to FIG. 14, a hub assembly for the drive system may include a hub 70 configured as a circular disc-like structure with multiple studs 72 extending from an outer face of the hub 70. The studs 72 may be used for mounting a wheel to the hub 70. The hub 70 may include several circular apertures distributed around the face of the hub 70 for fastening purposes.

At a center of the hub 70, a power generating member 30 may be positioned with a hub aperture 32 that extends through the hub 70 and the power generating member 30. The power generating member 30 may have a cylindrical configuration and may be integrated with the hub 70. In some embodiments, the hub 70 may be coupled to the power generating member 30. In other cases, the hub 70 and the power generating member 30 may be formed as a single component being a hub with a power generating member.

The power generating member 30 may include a grooved drive 36 on an inner surface of the power generating member 30. The grooved drive 36 may comprise multiple grooves 38 arranged in a pattern. In some embodiments, the plurality of recessed grooves 38 may be evenly spaced around a circumference of the power generating member 30. The grooves 38 may be configured to receive hydraulic fluid and convert fluid pressure into rotational motion of the power generating member 30 and the hub 70.

The hub aperture 32 may provide a central opening through which an axle can be inserted, allowing the hub 70 and power generating member 30 to rotate about the axle. Two tapered bearings may be positioned within the hub aperture 32 that extends through the hub 70 and the power generating member 30. The two tapered bearings may be coupled to the axle to support rotation of the hub 70 around the axle. In some embodiments, a rod wiper 62 may be positioned around the power generating member 30 and adjacent the hub 70.

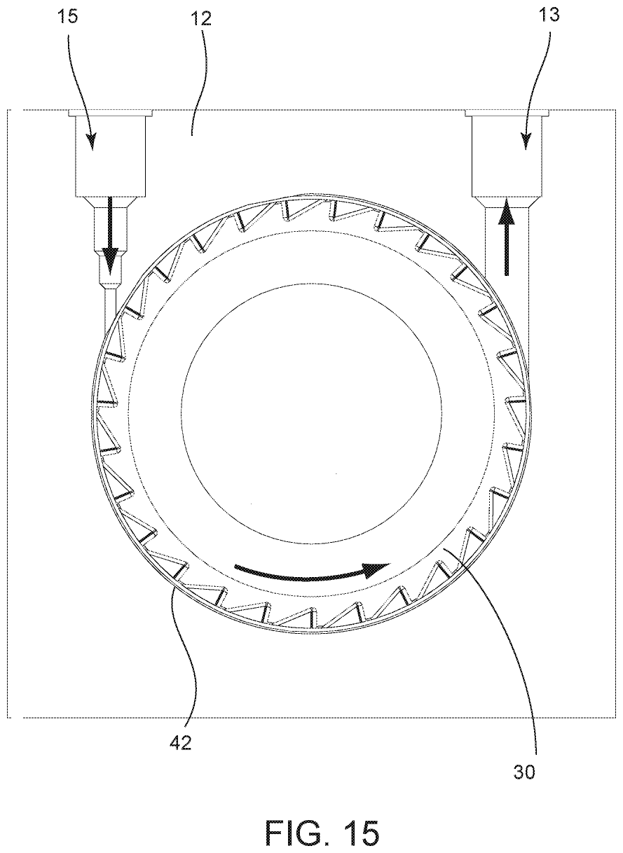

Referring to FIG. 15, the operation of the drive system 10 for aircraft landing gear involves a method of flowing hydraulic fluid from the aircraft through the manifold to rotate the wheel to a predetermined speed prior to landing. The drive system 10 operates by receiving hydraulic fluid from the aircraft's hydraulic system and directing the fluid through a controlled flow path to generate rotational motion.

The method of operating the drive system 10 may begin by providing a manifold 12 having a fluid inlet orifice 13, a fluid outlet orifice 13, an inner volume 14, and a pressure chamber 40 within the inner volume 14. The method may further include providing a power generating member 30 within the inner volume 14 of the manifold 12, where the power generating member 30 may be coupled to a hub 70 configured for attachment to a wheel of the aircraft landing gear.

During operation, hydraulic fluid from the aircraft may flow into the manifold 12 through the inlet orifice 13 and into the pressure chamber 40. As shown in FIG. 15, the hydraulic fluid may enter through the inlet orifice 13 and may be directed toward the power generating member 30 positioned centrally within the manifold 12. The power generating member 30 may comprise a grooved drive 36 with a plurality of recessed grooves 38 formed in an outer surface thereof, and the plurality of recessed grooves 38 may be evenly spaced around a circumference of the power generating member 30.

The method may include directing the hydraulic fluid through the pressure chamber 40 to engage the power generating member 30 to rotate the power generating member 30 and the hub 70. In some embodiments, directing the hydraulic fluid through the pressure chamber 40 may comprise engaging the plurality of recessed grooves 38 with the hydraulic fluid. The pressure chamber 40 may comprise a pressure channel 42 formed in a cylindrical surface 11 of the inner volume 14, and directing the hydraulic fluid through the pressure chamber 40 may comprise flowing the hydraulic fluid through the pressure channel 42 to engage the power generating member 30.

As illustrated in FIG. 15, the hydraulic fluid may engage the grooves 38 of the power generating member 30, causing rotational motion as indicated by the curved arrow at the bottom of the power generating member 30. The engagement of the hydraulic fluid with the grooved drive 36 may convert fluid pressure into mechanical rotation, thereby rotating the wheel of the aircraft landing gear to a predetermined speed prior to landing the aircraft.

The predetermined speed rotation aspect of the drive system 10 may provide substantial operational benefits. The drive system 10 may rotate the wheels up to a predetermined speed prior to landing the airplane, which may be calculated based on the aircraft's approach speed and landing conditions. In some embodiments, the predetermined speed may correspond to the expected ground speed of the aircraft upon touchdown. It will be understood that the manifold 12 and the power generating member 30 are configured to prevent a pump action by and damage to the hydraulic motor 10 in the event that the power generating member 30 is suddenly rotated faster than the fluid is being supplied to the hydraulic motor 10 during landing. Additionally, It will be understood that the manifold 12 and the power generating member 30 are configured to prevent damage to the hydraulic motor 10 in the event that the power generating member 30 is suddenly rotated slower than the fluid is being supplied to the hydraulic motor 10 during landing.

The tire tread preservation aspect of the drive system 10 may reduce the amount of loss of tire tread and may increase tire life. When the plane lands with the wheels already rotating at the predetermined speed, the sudden transition from stationary wheels to rolling contact with the runway may be eliminated or substantially reduced. This reduction in abrupt wheel acceleration may minimize the scrubbing action that typically occurs when stationary tires first contact the runway surface, thereby preserving tire tread and extending tire service life.

The runway rubber reduction aspect of the drive system may reduce runway clearing requirements. As the plane lands with the wheels already rotating, the amount of rubber deposited on the runway surface may be substantially reduced compared to conventional landing gear systems. The reduced rubber deposition may decrease the frequency of runway cleaning operations and may improve runway surface conditions for subsequent aircraft operations.

The method may further include flowing hydraulic fluid from the pressure chamber 40 and out of the manifold 12 through the outlet orifice 15. In some embodiments, flowing hydraulic fluid from the pressure chamber may comprise relieving pressure as the hydraulic fluid flows from the pressure channel 42 into a pressure relief channel formed in the cylindrical surface 11 and extending from the pressure channel 42 past the outlet orifice 15.

The method may also include providing the power generating member 30 coupled to the hub 70 with a hub aperture 32 extending through the hub 70 and the power generating member 30, and may further comprise supporting rotation of the hub 70 around an axle 60 extending through the hub aperture 32 using two tapered bearings 64 and 66 positioned within the hub aperture 32. The tapered bearings 64 and 66 may facilitate smooth rotation of the hub 70 and power generating member 30 assembled around the axle 60 during the hydraulic fluid engagement process.

The embodiments and examples set forth herein were presented in order to best explain the present invention and its practical application and to thereby enable those of ordinary skill in the art to make and use the invention. However, those of ordinary skill in the art will recognize that the foregoing description and examples have been presented for the purposes of illustration and example only. The description as set forth is not intended to be exhaustive or to limit the invention to the precise form disclosed. Many modifications and variations are possible in light of the teachings above without departing from the spirit and scope of the forthcoming claims.

1. A drive system for aircraft landing gear, comprising:
a manifold comprising a fluid inlet orifice, a fluid outlet orifice, and an inner volume with a pressure chamber formed therein;
a power generating member positioned within the inner volume of the manifold, the power generating member comprising a grooved drive with a plurality of recessed grooves formed in an outer surface thereof;
a hub coupled to the power generating member, the hub configured for attachment to a wheel of the aircraft landing gear;
a hub aperture extending through the hub and the power generating member;
an axle extending through the hub aperture; and
two tapered bearings positioned within the hub aperture and coupled to the axle, wherein the hub is configured to rotate around the axle when hydraulic fluid from the aircraft flows through the manifold and engages the grooved drive of the power generating member.

2. The drive system of claim 1, wherein the inner volume comprises a a cylindrical surface with a diameter, and the power generating member comprises a shaft having a diameter that is smaller than the diameter of the cylindrical surface.

3. The drive system of claim 2, wherein the pressure chamber comprises a pressure channel formed in the cylindrical surface of the inner volume, the pressure channel overlapping the fluid inlet orifice and extending toward the outlet orifice.

4. The drive system of claim 3, wherein the pressure chamber further comprises a seal extending from a first end of the pressure channel to above the fluid inlet orifice and on either side of the pressure channel, such that flow of hydraulic fluid is inhibited between the power generating member and the seal and directed through the pressure channel while engaging the grooved drive.

5. The drive system of claim 1, wherein the plurality of recessed grooves are evenly spaced around a circumference of the power generating member.

6. The drive system of claim 1, wherein the manifold and the power generating member are configured to prevent a pump action by the hydraulic motor in the event that the power generating member is rotated faster than the fluid is being supplied to the hydraulic motor during landing.

7. A drive system for aircraft landing gear, comprising:
a hydraulic motor comprising a manifold with an inner volume comprising a cylindrical surface, a fluid inlet orifice, and a fluid outlet orifice;
a power generating member disposed within the inner volume, the power generating member comprising a shaft having a diameter smaller than a diameter of the cylindrical surface and including a grooved drive with a plurality of recessed grooves evenly spaced around a circumference of the power generating member;
a pressure chamber formed in the manifold and comprising a pressure channel formed in the cylindrical surface, the pressure channel overlapping the inlet orifice and extending toward the outlet orifice;
a hub coupled to the power generating member and configured to mount to a wheel of the aircraft landing gear; and
an axle extending through the hub and the power generating member, wherein hydraulic fluid flowing through the inlet orifice engages the grooved drive through the pressure channel to rotate the power generating member and the hub.

8. The drive system of claim 7, wherein the pressure chamber further comprises a seal extending from a first end of the pressure channel to above the fluid inlet orifice and on either side of the pressure channel, such that flow of hydraulic fluid is inhibited between the power generating member and the seal and directed through the pressure channel while engaging the grooved drive.

9. The drive system of claim 8, wherein the power generating member comprises a raised surface having a width greater than the width of the pressure channel, the raised surface extending around the circumference of the power generating member, wherein the plurality of recessed grooves are formed in the raised surface.

10. The drive system of claim 9, further comprising a pressure relief channel formed in the cylindrical surface and extending from the pressure channel past the fluid outlet orifice, wherein pressure is relieved as hydraulic fluid flows from the pressure channel into the pressure relief channel.

11. The drive system of claim 10, wherein a width of the pressure channel is equal to or greater than a width of the plurality of recessed grooves of the grooved drive and wherein the pressure chamber further comprises a seal between formed by the raided surface and the inner surface of inner volume, the seal extending from a first end of the pressure channel to above the fluid inlet orifice and on either side of the pressure channel, such that flow of hydraulic fluid is inhibited between the power generating member and the seal and directed through the pressure channel while engaging the grooved drive.

12. The drive system of claim 7, further comprising two tapered bearings positioned within a hub aperture that extends through the hub and the power generating member, wherein the two tapered bearings are coupled to the axle to support rotation of the hub around the axle.

13. The drive system of claim 7, wherein the manifold and the power generating member are configured to prevent a pump action by and damage to the hydraulic motor in the event that the power generating member is suddenly rotated faster than the fluid is being supplied to the hydraulic motor during landing.

14. The drive system of claim 7, wherein the manifold and the power generating member are configured to prevent damage to the hydraulic motor in the event that the power generating member is suddenly rotated slower than the fluid is being supplied to the hydraulic motor during landing.

15. A method of operating a drive system for aircraft landing gear, comprising:
providing a manifold comprising a fluid inlet orifice, a fluid outlet orifice, an inner volume, and a pressure chamber within the inner volume;
providing a power generating member within the inner volume of the manifold, the power generating member being coupled to a hub configured for attachment to a wheel of the aircraft landing gear;
flowing hydraulic fluid from the aircraft into the manifold through the inlet orifice and into the pressure chamber;
directing the hydraulic fluid through the pressure chamber to engage the power generating member to rotate the power generating member and the hub;
rotating the wheel of the aircraft landing gear to a predetermined speed prior to landing the aircraft; and
flowing hydraulic fluid from the pressure chamber and out of the manifold through the outlet orifice.

16. The method of claim 15, wherein the power generating member comprises a grooved drive with a plurality of recessed grooves formed in an outer surface thereof, and directing the hydraulic fluid through the pressure chamber comprises engaging the plurality of recessed grooves with the hydraulic fluid.

17. The method of claim 16, further comprising preventing a pump action by the hydraulic motor in the event that the power generating member is rotated faster than the fluid is being supplied to the hydraulic motor during landing and preventing damage to the hydraulic motor in the event that the power generating member is suddenly rotated slower than the fluid is being supplied to the hydraulic motor during landing.

18. The method of claim 15, wherein the pressure chamber comprises a pressure channel formed in a cylindrical surface of the inner volume, and directing the hydraulic fluid through the pressure chamber comprises flowing the hydraulic fluid through the pressure channel to engage the power generating member.

19. The method of claim 18, wherein flowing hydraulic fluid from the pressure chamber comprises relieving pressure as the hydraulic fluid flows from the pressure channel into a pressure relief channel formed in the cylindrical surface and extending from the pressure channel past the outlet orifice.

20. The method of claim 15, wherein providing the power generating member comprises providing the power generating member coupled to the hub with a hub aperture extending through the hub and the power generating member, and further comprising supporting rotation of the hub around an axle extending through the hub aperture using two tapered bearings positioned within the hub aperture.
